(19) United States
(12) Patent Application Publication
(10) Pub. No.: US 2022/0263288 A1
(43) Pub. Date: Aug. 18, 2022

(54) SEMICONDUCTOR LASER DEVICE

(71) Applicant: Panasonic Corporation, Osaka (JP)

(72) Inventor: Shinichiro NOZAKI, Osaka (JP)

(21) Appl. No.: 17/627,247

(22) PCT Filed: Aug. 17, 2020
(86) PCT No.: PCT/JP2020/031036

§ 371 Date: Jan. 14, 2022

(30) Foreign Application Priority Data
Aug. 26, 2019 (JP) 2019-153653

(51) Int. Cl. H01S 5/042; H01S 5/22

(52) U.S. Cl. CPC H01S 5/04256; H01S 5/22; H01S 5/04254

(57) ABSTRACT

A semiconductor laser device, which outputs laser light, includes: a substrate; an n-type semiconductor layer disposed above the substrate; a light emitting layer disposed above the n-type semiconductor layer; a p-type semiconductor layer disposed above the light emitting layer; and at least one p electrode disposed above the p-type semiconductor layer. At least one groove is formed that extends from an upper surface of the p-type semiconductor layer to reach a lower surface of the light emitting layer, and extends in a resonance direction of the laser light. A remaining length, which is a distance between an output end face from which the laser light is outputted and a portion of each groove that is closest to the at least one p electrode, is longer than a non-injection region length, which is a distance between the output end face and the at least one p electrode.

### CROSS-REFERENCE OF RELATED APPLICATIONS

This application is the U.S. National Phase under 35 U.S.C. § 371 of International Patent Application No. PCT/JP2020/031036, filed on Aug. 17, 2020, which in turn claims the benefit of Japanese Application No. 2019-153653, filed on Aug. 26, 2019, the entire disclosures of which Applications are incorporated by reference herein.

### TECHNICAL FIELD

The present disclosure relates to a semiconductor laser device.

### BACKGROUND ART

Laser light has been used for processing purposes. Against this backdrop, high-power and highly efficient laser light sources are required. Semiconductor laser devices are utilized as high-power and highly efficient laser light sources. Known as such high-power semiconductor laser devices are light emitting array devices in which light emitting points serving as heat sources are dispersedly arranged in array. A plurality of laser light beams from such a light emitting array device are synthesized into a single laser light beam for utilization purposes, using an optical system. In this case, warpage, when occurring in the light emitting array device, causes misalignment of spaces between light emitting points. This reduces the efficiency of coupling between the optical system and the laser light from the light emitting array device. Consequently, an overall efficiency of the light sources decreases.

The semiconductor laser device disclosed in Patent Literature (PTL) 1 is an exemplary background art for solving the foregoing problem. Such semiconductor laser device includes, between light emitting points, a groove portion that divides a p-type semiconductor layer and a light emitting layer. According to the semiconductor laser device disclosed in PTL 1, such groove portion alleviates strain that occurs in a semiconductor layer, thereby preventing warpage in the semiconductor laser device.

### CITATION LIST

### Patent Literature

[PTL 1] Japanese Unexamined Patent Application Publication No. 2006-54277

### SUMMARY OF INVENTION

### Technical Problem

However, the present inventor has found the following point. That is to say, when a non-injection region to which no electric current is injected is formed in the vicinity of the output end face of the semiconductor laser device from which laser light is outputted, such a groove portion as the one disclosed in PTL 1 reduces an effective bandgap in the non-injection region in the light emitting layer, thus increasing laser light absorption. Laser light absorption in such non-injection region can result in a catastrophic optical damage (COD).

The present disclosure solves such problem, and its aim is to provide a semiconductor laser device capable of reducing a decrease in an effective bandgap in a non-injection region.

### Solution to Problem

To solve the foregoing problem, an aspect of the semiconductor laser device according to the present disclosure is a semiconductor laser device that outputs laser light. Such semiconductor laser device includes: a substrate; an n-type semiconductor layer disposed above the substrate; a light emitting layer disposed above the n-type semiconductor layer; a p-type semiconductor layer disposed above the light emitting layer; and at least one p electrode disposed above the p-type semiconductor layer. Here, at least one groove is formed that extends from an upper surface of the p-type semiconductor layer to reach a lower surface of the light emitting layer, and extends in a resonance direction of the laser light, and a remaining length is longer than a non-injection region length, the remaining length being a distance between an output end face from which the laser light is outputted and a portion of the at least one groove, the non-injection region length being a distance between the output end face and the at least one p electrode, the portion being a portion that is closest to the at least one p electrode.

### Advantageous Effects of Invention

According to the present disclosure, it is possible to provide a semiconductor laser device capable of reducing a decrease in an effective bandgap in a non-injection region.

### BRIEF DESCRIPTION OF DRAWINGS

FIG. 1A is a schematic cross-sectional view of the configuration of the semiconductor laser device according to the background art.

FIG. 1B is a graph showing a relation between the width of an n-type semiconductor layer in the semiconductor laser device according to the background art and warpage in the semiconductor laser device.

FIG. 2 is a diagram showing the result of analyzing the semiconductor laser device according to the background art, using X-ray diffraction.

FIG. 3 is a graph showing a relation between the ratio of the groove width and the position of a Raman peak in the semiconductor laser device according to the background art.

FIG. 4 is a schematic diagram for explaining a relation between the band structure and compression strain in a light emitting layer in the semiconductor laser device according to the background art.

FIG. 5A is a schematic perspective view of an overall configuration of a semiconductor laser device according to Embodiment 1.

FIG. 5B is a partially enlarged plan view of the semiconductor laser device according to Embodiment 1.

FIG. 5C is a first cross-sectional view of the semiconductor laser device according to Embodiment 1.

FIG. 5D is a second cross-sectional view of the semiconductor laser device according to Embodiment 1.

FIG. 5E is a third cross-sectional view of the semiconductor laser device according to Embodiment 1.

FIG. 6A is a schematic perspective view of an overall configuration of a semiconductor laser device according to Embodiment 2.

FIG. 6B is a partially enlarged plan view of the semiconductor laser device according to Embodiment 2.

FIG. 6C is a first cross-sectional view of the semiconductor laser device according to Embodiment 2.

FIG. 6D is a second cross-sectional view of the semiconductor laser device according to Embodiment 2.

FIG. 7A is a schematic perspective view of an overall configuration of a semiconductor laser device according to Embodiment 3.

FIG. 7B is a partially enlarged plan view of the semiconductor laser device according to Embodiment 3.

FIG. 7C is a first cross-sectional view of the semiconductor laser device according to Embodiment 3.

FIG. 7D is a second cross-sectional view of the semiconductor laser device according to Embodiment 3.

FIG. 8A is a first cross-sectional view of a semiconductor laser device according to Embodiment 4.

FIG. 8B is a second cross-sectional view of the semiconductor laser device according to Embodiment 4.

FIG. 9A is a schematic plan view of an overall configuration of a semiconductor laser device according to Embodiment 5.

FIG. 9B is a first cross-sectional view of the semiconductor laser device according to Embodiment 5.

FIG. 9C is a second cross-sectional view of the semiconductor laser device according to Embodiment 5.

### DESCRIPTION OF EMBODIMENTS

### (Underlying Knowledge Forming Basis of the Present Disclosure)

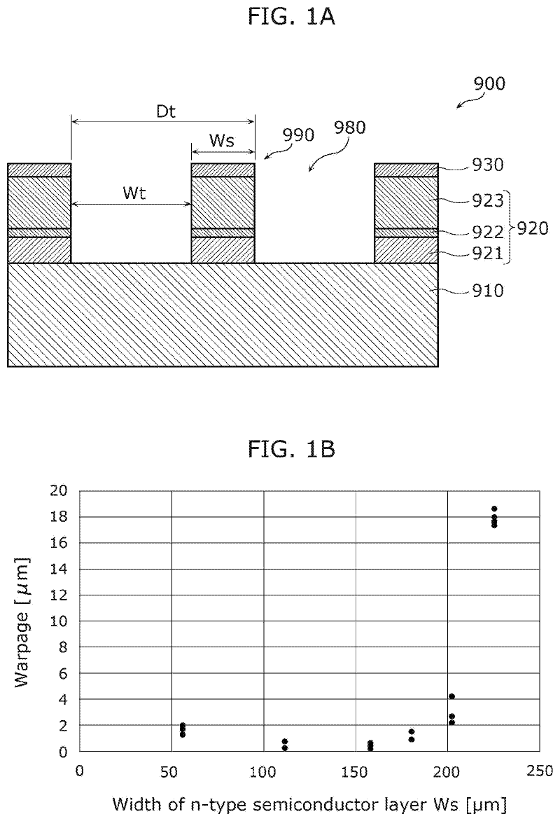

With reference to FIG. 1A through FIG. 4, the underlying knowledge that forms the basis of the present disclosure will be described before describing the embodiments according to the present disclosure. FIG. 1A is a schematic cross-sectional view of the configuration of semiconductor laser device 900 according to the background art.

As shown in FIG. 1A, semiconductor laser device 900, which is a device that outputs laser light, includes substrate 910, crystal growth layer 920, and p electrode 930. Semiconductor laser device 900 includes a plurality of grooves 980 that extend from the upper surface to reach the lower surface of crystal growth layer 920 and extend in a direction parallel to the resonance direction of laser light. Disposed between two adjacent grooves 980 is light emitting portion 990 that outputs laser light. Semiconductor laser device 900 is 2 mm in length in the resonance direction, and light emitting portion 990 is 9 mm in length in the array direction.

Substrate 910 is a GaN substrate with the thickness of 80 μm.

Crystal growth layer 920 is a semiconductor layer with the thickness on the order of 3.6 μm that is crystal grown on a principal surface of substrate 910. Crystal growth layer 920 includes n-type semiconductor layer 921, light emitting layer 922, and p-type semiconductor layer 923.

n-type semiconductor layer 921 is an n-type clad layer with the thickness of 3 μm comprising n-Al_{0.03}Ga_{0.97}N.

Light emitting layer 922 is a quantum well active layer including two well layers each with the thickness of 5 nm and comprising In_{0.06}Ga_{0.94}N and a barrier layer with the thickness of 10 nm comprising GaN, where the well layers and the barrier layer are alternately laminated.

p-type semiconductor layer 923 is a p-type clad layer including a superlattice layer with the thickness of 0.6 μm, where 100 layers each with the thickness of 3 nm and comprising p-Al_{0.06}Ga_{0.94}N and 100 layers each with the thickness of 3 nm and comprising GaN are alternately laminated.

p electrode 930 is a laminated film including Pd and Pt that are laminated in stated order from the side of p-type semiconductor layer 923.

Although not illustrated, an n electrode disposed on the lower surface of substrate 910 is also included in semiconductor laser device 900.

With reference to FIG. 1B, the following describes a relation between the ratio of width Wt of groove 980 of semiconductor laser device 900 as shown in FIG. 1A and warpage of semiconductor laser device 900. FIG. 1B is a graph showing a relation between width Ws of n-type semiconductor layer 921 in semiconductor laser device 900 according to the background art and warpage in semiconductor laser device 900. The graph shown in FIG. 1B is based on the results of conducting three similar experiments. In the experiments, grooves 980 have a fixed pitch Dt of 225 μm. Stated differently, width Wt of groove 980 can be indicated as 225-Ws. In FIG. 1B, the point on the lateral axis corresponding to 225 μm indicates that the width of groove 980 is 0. In this case, warpage of semiconductor laser device 900 is on the order of 18 μm. Meanwhile, when grooves 980 are formed (i.e., when width Ws of n-type semiconductor layer 921 is less than 225 μm), warpage of semiconductor laser device 900 is reduced to 5 μm or less.

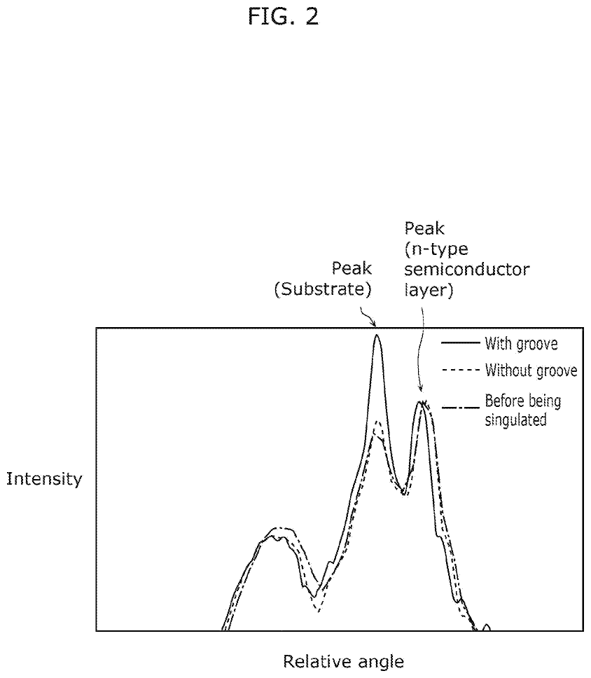

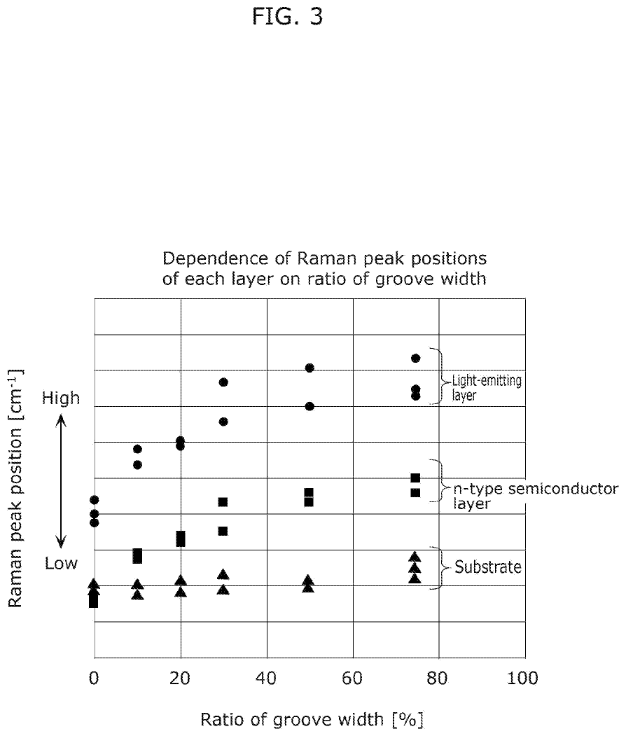

The present inventor has found that the formation of grooves 980 results in significant reduction in warpage of semiconductor laser device 900, while affecting the properties of semiconductor laser device 900. With reference to FIG. 2 and FIG. 3, the following describes affects caused by grooves 980 formed in semiconductor laser device 900. FIG. 2 is a diagram showing the result of analyzing semiconductor laser device 900 according to the background art, using X-ray diffraction (2θ/ω). In FIG. 2, the lateral axis represents a relative angle and the vertical axis represents the intensity of an X-ray. Also, in FIG. 2, the solid line represents the result of analyzing semiconductor laser device 900 in which grooves 980 are formed, and the broken line represents the result of analyzing semiconductor laser device 900 in which no groove 980 is formed. Also, the dash-dot-dash line represents the result of analyzing semiconductor laser device 900 before being singulated. Stated differently, the dash-dot-dash line represents the result of analyzing a laminated body which is obtained by forming crystal growth layer 920 on a wafer comprising GaN and on which no groove 980 is formed. Of the three significant peaks shown in FIG. 2, the rightmost peak corresponds to the crystal lattice dimension of n-type semiconductor layer 921 in the c-axis direction, and the peak in the vicinity of the center corresponds to the crystal lattice dimension of substrate 910 in the c-axis direction.

As shown in FIG. 2, no significant difference is present between semiconductor laser device 900 before being singulated (indicated by the dash-dot-dash line) and semiconductor laser device 900 in which no groove 980 is formed (indicated by the broken line). In semiconductor laser device 900 in which grooves 980 are formed, however, the peak corresponding to the crystal lattice dimension, in the c-axis direction, of n-type semiconductor layer 921 comprising Al is located leftward compared to the peak corresponding to the crystal lattice dimension, in the c-axis direction, of n-type semiconductor layer 921 in another semiconductor laser device. Stated differently, semiconductor laser device 900 in which grooves 980 are formed has an increased crystal lattice dimension of n-type semiconductor layer 921 in the c-axis direction. Stated differently, n-type semiconductor layer 921 has a reduced crystal lattice dimension in the a-axis direction.

In this case, it is conceivable that light emitting layer 922 including In is subjected to higher compression strain because such light emitting layer 922 has a greater lattice constant in the a-axis direction than that of n-type semiconductor layer 921. With reference to FIG. 3, the following describes the strength of compression strain in each layer in semiconductor laser device 900. FIG. 3 is a graph showing a relation between the ratio of the groove width and the position of a Raman peak in semiconductor laser device 900 according to the background art. In FIG. 3, the lateral axis represents ratio Wt/(Wt+Ws) of groove width Wt and the vertical axis represents the position of a Raman peak.

As shown in FIG. 3, the greater the ratio of groove width Wt in n-type semiconductor layer 921 and light emitting layer 922 is, the larger the number of waves becomes indicating the positions of Raman peaks. Stated differently, a greater ratio of groove width Wt in n-type semiconductor layer 921 and light emitting layer 922 results in higher compression strain.

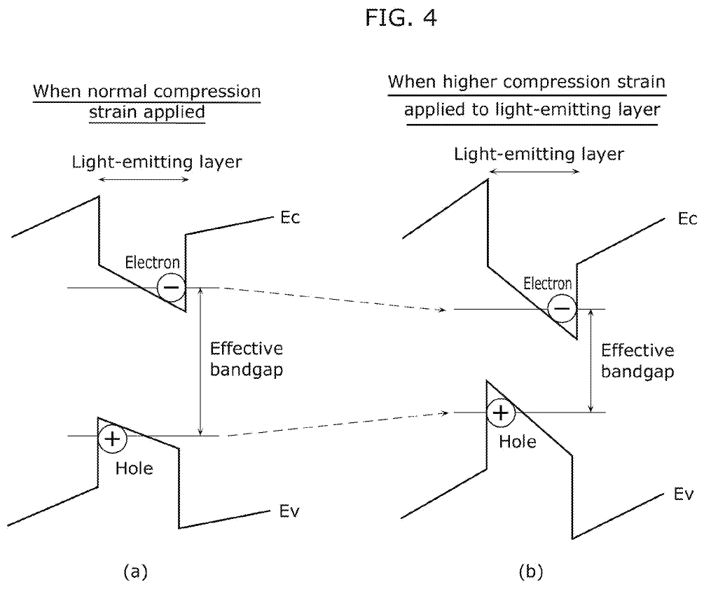

With reference to FIG. 4, the following describes a relation between the band structure and compression strain in light emitting layer 922. FIG. 4 is a schematic diagram for explaining a relation between the band structure and compression strain in light emitting layer 922 in semiconductor laser device 900 according to the background art. In the schematic diagram in FIG. 4, (a) indicates the band structure in the vicinity of light emitting layer 922 in semiconductor laser device 900 in which no groove 980 is formed (i.e., light emitting layer 922 is subjected to normal compression strain). In the schematic diagram, (b) indicates the band structure in the vicinity of light emitting layer 922 in semiconductor laser device 900 in which grooves 980 are formed, in the case where light emitting layer 922 is subjected to higher compression strain. In (a) and (b) in the schematic diagram, the upper bold lines represent conductive band Ec and the lower bold lines represent valence band Ev.

When subjected to higher compression strain, light emitting layer 922 having the band structure as shown in (a) in the schematic diagram of FIG. 4 is placed under the application of a greater polarization electric field. For this reason, a change occurs in the band structure as shown in (b) in the schematic diagram of FIG. 4. With this, a gap between the minimum value of energy of electrons in the conductive band and the maximum value of energy of holes in the valence band, i.e., an effective bandgap, decreases. Here, an effective bandgap is defined, for example, by a bandgap corresponding to the wavelength that takes the peak value in photoluminescence or absorption spectra in light emitting layer 922.

In semiconductor laser device 900 according to the background art, a non-injection region into which no electric current is injected is provided, in some cases, between the output end face from which laser light is outputted and the edge portion of p electrode 930 at the side of output end face. In this cases, when an effective bandgap in the non-injection region decreases as described above, laser light absorption increases in the non-injection region. Such light absorption raises the temperature of light emitting layer 922, thus further reducing an effective bandgap. Consequently, the amount of light absorption further increases. As described above, a positive feedback of the amount of light absorption occurs in light emitting layer 922, as a result of which COD can occur.

As described above, when grooves are formed in the semiconductor laser device including the non-injection region to prevent warpage, an effective bandgap decreases in the non-injection region and consequently COD can occur.

In view of the above, the present disclosure provides a semiconductor laser device capable of preventing a decrease in an effective bandgap in a non-injection region.

To solve the foregoing problem, an aspect of the semiconductor laser device according to the present disclosure is a semiconductor laser device that outputs laser light. Such semiconductor laser device includes: a substrate; an n-type semiconductor layer disposed above the substrate; a light emitting layer disposed above the n-type semiconductor layer; a p-type semiconductor layer disposed above the light emitting layer; and at least one p electrode disposed above the p-type semiconductor layer. Here, at least one groove is formed that extends from an upper surface of the p-type semiconductor layer to reach a lower surface of the light emitting layer, and extends in a resonance direction of the laser light, and a remaining length is longer than a non-injection region length, the remaining length being a distance between an output end face from which the laser light is outputted and a portion of the at least one groove, the non-injection region length being a distance between the output end face and the at least one p electrode, the portion being a portion that is closest to the at least one p electrode.

As described above, the remaining length of the groove is longer than the non-injection region length. This reduces a decrease in an effective bandgap in the non-injection region caused by the formation of the groove. This thus prevents the light absorption in the non-injection region, thereby enabling the semiconductor laser device capable of preventing the occurrence of COD.

Also, in an aspect of the semiconductor laser device according to the present disclosure, in the light emitting layer, an effective bandgap may be greater in a non-injection region located between an injection region located directly below the at least one p electrode and the output end face than in the injection region.

This reduces the light absorption in the non-injection region. In other words, this configuration enables a window structure in the non-injection region.

Also, in an aspect of the semiconductor laser device according to the present disclosure, the width of the at least one groove may gradually decrease from the portion of the at least one groove that is closest to the at least one p electrode toward the output end face.

Depending on the distance between the groove and the p electrode, stress to be applied to the light emitting layer changes and so does the reflective index of the light emitting layer. As in such case, a rapid change in the reflective index of the light emitting layer in a light propagation direction disturbs the light propagation. The semiconductor laser device according to the present disclosure whose groove gradually decreases in width is thus capable of attenuating changes in the reflective index of the light emitting layer, thereby preventing the disturbance of light propagation.

Also, in an aspect of the semiconductor laser device according to the present disclosure, the remaining length may be 50 μm or greater.

It is empirically known that, in the case of forming the output end face of the semiconductor laser device by cleavage, the resulting cleavage surface is more favorable when the strain in each of the semiconductor layers is higher. Also, on the basis of the underlying knowledge of the present inventor, a region is formed, around 100 μm from each groove, in which strain is retained. Here, to form semiconductor laser devices in a symmetric position with the respective cleavage surfaces serving as symmetric planes, under a condition that the remaining length is 50 μm or greater, the distance between two grooves located in a symmetric position relative to the cleavage surfaces before cleavage is 100 μm or greater. As such, strain is retained between the two grooves that are symmetrically located with respect to the cleavage surfaces at least before cleavage, thereby providing a favorable cleavage surface. This increases the reliability of the semiconductor laser device.

Also, in an aspect of the semiconductor laser device according to the present disclosure, the remaining length may be 100 μm or greater.

It is empirically known that, in the case of forming the output end face of the semiconductor laser device by cleavage, the resulting cleavage surface is more favorable when the strain in each of the semiconductor layers is higher. Also, on the basis of the underlying knowledge of the present inventor, a region is formed, around 100 μm from each groove, in which strain is retained. The remaining length of 100 μm or greater enables strain to be retained in the vicinity of the cleavage surface not only before but also after cleavage. This provides a favorable cleavage surface, thus increasing the reliability of the semiconductor laser device.

Also, in an aspect of the semiconductor laser device according to the present disclosure, the remaining length may be 50 μm or greater and less than 100 μm.

It is empirically known that, in the case of forming the output end face of the semiconductor laser device by cleavage, the resulting cleavage surface is more favorable when the strain in each of the semiconductor layers is higher. Also, on the basis of the underlying knowledge of the present inventor, a region is formed, around 100 μm from each groove, in which strain is retained. In view of this, the remaining length of 50 μm or greater enables strain to be retained in the vicinity of the cleavage surface before cleavage, and the remaining length of less than 100 μm reduces strain in the vicinity of the cleavage surface after cleavage. The semiconductor laser device according to the present disclosure is thus capable of both having a favorable cleavage surface and reducing chip warpage.

Also, in an aspect of the semiconductor laser device according to the present disclosure, each of the substrate, the n-type semiconductor layer, and the light emitting layer may include a nitride semiconductor.

The use of a nitride semiconductor in each of the semiconductor layers can cause variations in an effective bandgap in the light emitting layer as a result of the formation of grooves. Having the remaining length that is longer than non-injection region length, however, the semiconductor laser device according to the present disclosure is capable of reducing a decrease in an effective bandgap in the non-injection region.

Also, in an aspect of the semiconductor laser device according to the present disclosure, the at least one p electrode may include a plurality of p electrodes that are arranged in a direction perpendicular to the resonance direction.

The semiconductor laser device including a plurality of p electrodes serves as an array semiconductor laser device.

Also, in an aspect of the semiconductor laser device according to the present disclosure, the at least one groove may extend to the output end face.

As described above, the groove extends to the output end face of the semiconductor laser device. With this, it is possible to reduce the strain in each of the semiconductor layers, thereby reducing warpage of the semiconductor laser device.

Hereinafter, the embodiments according to the present disclosure are described with reference to the accompanying Drawings Each of the exemplary embodiments described below shows a specific example. The numerical values, shapes, materials, elements, the arrangement and connection of the elements, etc. shown in the following exemplary embodiments are mere examples, and therefore do not limit the scope of the present disclosure.

Note that the drawings are schematic diagrams, and thus they are not necessarily illustrated exactly. For example, the drawings are not necessarily illustrated to the same scale. Also, substantially the same elements are assigned the same reference marks throughout the drawings, and their repetitive description will be omitted or simplified.

In the present description, the terms “upper” and “lower” should not be construed as indicating an upper direction (vertically above) and a lower direction (vertically below) in absolute space recognition. The terms “upper” and “lower” are used as terms that are specified on the basis of a relative positional relation on the basis of the order in which layers of a laminated body are laminated. The terms “upper” and “lower” are also used not only for the case where two elements are spaced apart from each other and another element is present between such two elements, but also for the case where two elements are disposed in close contact with each other.

### Embodiment 1

The following describes the semiconductor laser device according to Embodiment 1.

### [1-1. Overall Configuration]

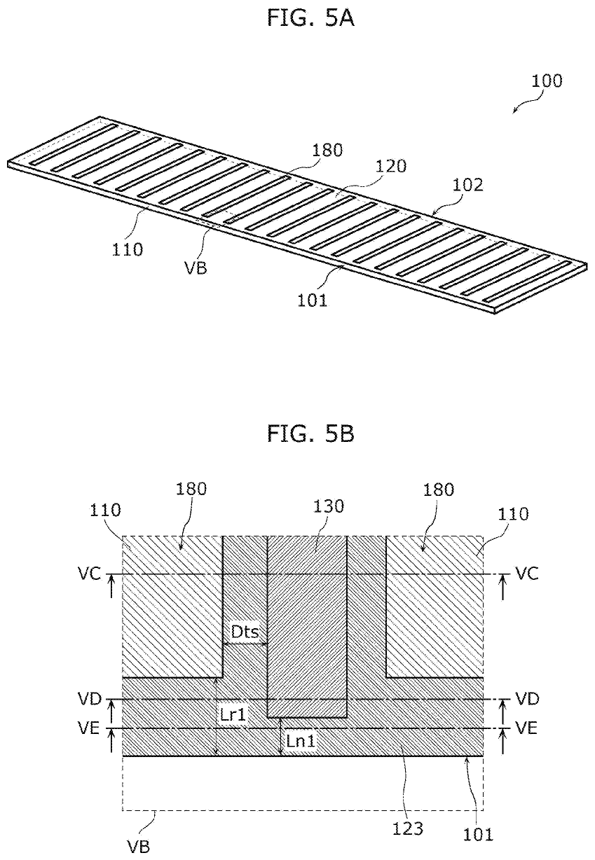

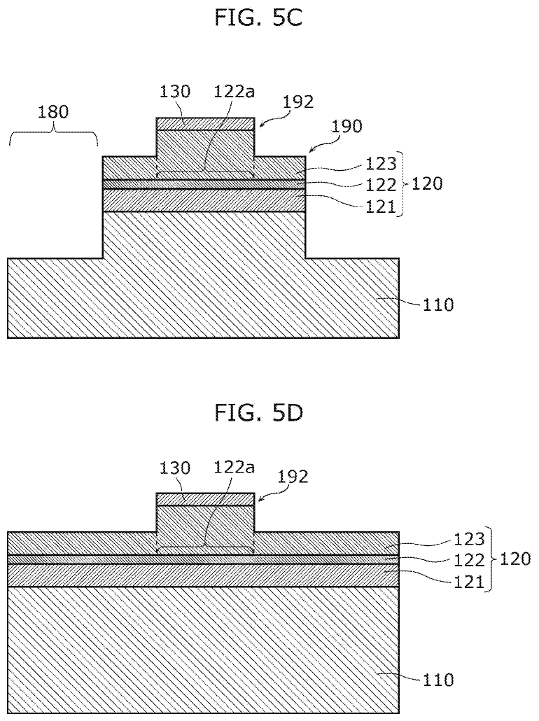

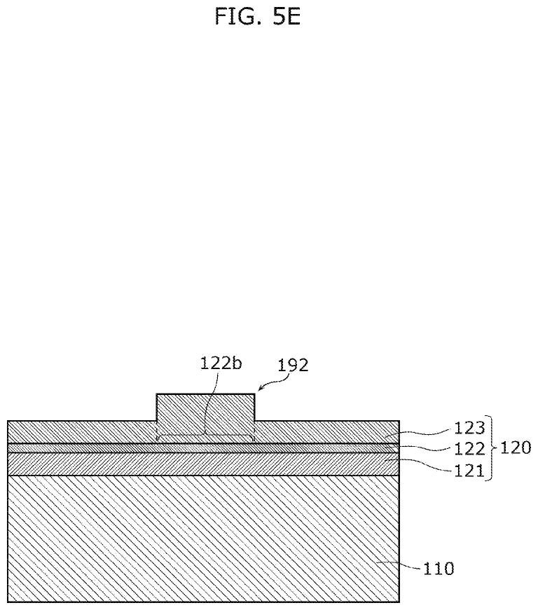

With reference to FIG. 5A through FIG. 5E, the following describes an overall configuration of the semiconductor laser device according to the present embodiment. FIG. 5A is a schematic perspective view of an overall configuration of semiconductor laser device 100 according to the present embodiment. FIG. 5B is a partially enlarged plan view of semiconductor laser device 100 according to the present embodiment. FIG. 5B shows an enlarged view of the inside of broken line frame VB in FIG. 5A. FIG. 5C, FIG. 5D, and FIG. 5E are first, second, and third cross-sectional views, respectively, of semiconductor laser device 100 according to the present embodiment. FIG. 5C, FIG. 5D, and FIG. 5E show cross-sections cut along VC-VC line, VD-VD line, and VE-VE line in FIG. 5B, respectively.

Semiconductor laser device 100 according to the present embodiment, which is a device that outputs laser light, includes, as shown in FIG. 5A, output end face 101 that is an end face from which laser light is outputted (i.e., the end face at the front side) and reflection end face 102 that is an end face at the rear side. Semiconductor laser device 100 includes substrate 110 and crystal growth layer 120 disposed on substrate 110. As shown in FIG. 5B through FIG. 5D, semiconductor laser device 100 further includes at least one p electrode 130. Also, as shown in FIG. 5A through FIG. 5C, at least one groove 180 is formed in semiconductor laser device 100.

Substrate 110 is a base of semiconductor laser device 100. In the present embodiment, substrate 110 is a GaN substrate with the thickness of 80 μm.

Crystal growth layer 120 is a semiconductor layer that is crystal gown on a principal surface of substrate 110. As shown in FIG. 5C through FIG. 5E, crystal growth layer 120 includes n-type semiconductor layer 121, light emitting layer 122, and p-type semiconductor layer 123. The layers of crystal growth layer 120 are formed by, for example, metal-organic chemical vapor deposition (MOCVD), etc.

As shown in FIG. 5A through FIG. 5C, grooves 180 are formed in crystal growth layer 120. With this, as shown in FIG. 5C, light emitting portion 190 is formed between two grooves 180. Groove 180 is formed by etching crystal growth layer 120 by, for example, wet etching, dry etching, etc. In the present embodiment, part of substrate 110 is also etched.

n-type semiconductor layer 121 is an n-type semiconductor layer disposed above substrate 110. In the present embodiment, n-type semiconductor layer 121 includes an n-type clad layer with the thickness of 3 μm comprising n-Al_{0.03}Ga_{0.97}N. n-type semiconductor layer 121 may include a layer other than the n-type clad layer. For example, n-type semiconductor layer 121 may include a buffer layer, etc. disposed between substrate 110 and the n-type clad layer.

Light emitting layer 122 is a layer disposed above n-type semiconductor layer 121. In the present embodiment, light emitting layer 122 includes a quantum well active layer including two well layers each with the thickness of 5 nm and comprising In_{0.06}Ga_{0.94}N and a barrier layer with the thickness of 10 nm comprising GaN, where the well layers and the barrier layer are alternately laminated. Light emitting layer 122 may include a layer other than the quantum well active layer. For example, light emitting layer 122 may include a light guide layer, etc.

p-type semiconductor layer 123 is a p-type semiconductor layer disposed above light emitting layer 122. In the present embodiment, p-type semiconductor layer 123 includes a p-type clad layer including a superlattice layer with the thickness of 0.6 μm, where each of 100 layers with the thickness of 3 nm comprising p-Al_{0.06}Ga_{0.94}N and each of 100 layers with the thickness of 3 nm comprising GaN are alternately laminated. p-type semiconductor layer 123 may include a layer other than the p-type clad layer. For example, p-type semiconductor layer 123 may include a p-type contact layer disposed between the p-type clad layer and p electrode 130. Also, as shown in FIG. 5C through 5E, ridge portion 192 is formed in p-type semiconductor layer 123. Ridge portion 192 is formed by etching p-type semiconductor layer 123 by, for example, wet etching, dry etching, etc.

p electrode 130 is an electrode disposed above p-type semiconductor layer 123. In the present embodiment, p electrode 130 is a laminated film including Pd and Pt that are laminated in stated order from the side of p-type semiconductor layer 123. The width of p electrode 130 (i.e., the dimension in a direction perpendicular to the resonance direction of laser light and the direction in which the layers are laminated) is, for example, between on the order of 16 μm and 30 μm, inclusive.

As shown in FIG. 5C and FIG. 5D, p electrode 130 is formed on ridge portion 192 of p-type semiconductor layer 123. Also, as shown in FIG. 5B and FIG. 5E, p electrode 130 is not disposed in the vicinity of output end face 101.

As described above, a region into which no electric current is injected is provided between output end face 101 and p electrode 130. With this, injection region 122a located directly below p electrode 130 (see FIG. 5C and FIG. 5D) and non-injection region 122b located between injection region 122a and output end face 101 (see FIG. 5E) are formed in light emitting layer 122. In the following, the distance between output end face 101 and p electrode 130 is referred to as non-injection region length Ln1.

Although not shown in the drawings, an n electrode disposed on the lower surface of substrate 110 is further included in semiconductor laser device 100. The n-electrode is, for example, a laminated film including Ti, Pt, and Au that are laminated in stated order from the side of substrate 110. p electrode 130 and the n electrode are formed by, for example, vacuum evaporation, etc.

### [1-2. Groove Structure and Operational Advantages]

With reference to FIG. 5A through FIG. 5E, the following describes in detail the structure and operational advantages of at least one groove 180 formed in semiconductor laser device 100 according to the present embodiment.

Groove 180 extends from the upper surface of p-type semiconductor layer 123 to reach the lower surface of light emitting layer 122 as shown in FIG. 5C, and extends in the resonance direction of laser light (i.e., the direction that is perpendicular to output end face 101 and reflection end face 102) as shown in FIG. 5A and FIG. 5B. In the present embodiment, as shown in FIG. 5C, groove 180 extends from the upper surface of substrate 110 to below. In the present embodiment, distance Dts between groove 180 and injection region 122a of light emitting layer 122 is 100 μm or less. For this reason, compression strain can occur in injection region 122a of light emitting layer 122 due to groove 180.

As shown in FIG. 5B, remaining length Lr1, which is the distance between output end face 101 and that portion of groove 180 which is closest to p electrode 130, is longer than non-injection region length Ln1, which is the distance between output end face 101 and p electrode 130.

As described above, remaining length Lr1 of groove 180 is longer than non-injection region length Ln1. This enables the distance between groove 180 and non-injection region 122b of light emitting layer 122 to be greater than the distance (Dts) between groove 180 and injection region 122a of light emitting layer 122. This reduces compression strain in non-injection region 122b attributable to groove 180, thus preventing a decrease in an effective bandgap in the non-injection region. Stated differently, in light emitting layer 122, an effective bandgap is greater in non-injection region 122b located between injection region 122a and output end face 101 than in injection region 122a located directly below p electrode 130. This thus prevents light absorption in non-injection region 122b, thereby enabling the semiconductor laser device capable of preventing the occurrence of COD.

In an example shown in FIG. 5B, the distance between groove 180 and p electrode 130 takes minimum value Dts at that portion of groove 180 which is closest to p electrode 130. Also in the present embodiment, as shown in FIG. 5B through FIG. 5E, no groove 180 is formed in the region from output end face 101 to remaining length Lr1. With this, it is possible to further increase the distance between groove 180 and non-injection region 122b of light emitting layer 122. Semiconductor laser device 100 according to the present embodiment is thus capable of further preventing the occurrence of COD.

Also, in the case where output end face 101 is formed by cleavage and groove 180 is formed in output end face 101, wrinkles (i.e., linear irregularities) stemming from groove 180 can be generated in output end face 101. Wrinkles generated in output end face 101, for example, result in a reduced reliability of semiconductor laser device 100 and increase variations in the output direction of laser light. In the present embodiment, no groove 180 is formed in output end face 101, thus reducing wrinkles generated in output end face 101. This consequently increases the reliability of semiconductor laser device 100 and reduces variations in the output direction of laser light.

Note that in the present embodiment, remaining length Lr1 may be 50 μm or greater. It is empirically known that, in the case of forming the output end face of semiconductor laser device 100 by cleavage, the resulting cleavage surface is more favorable when the strain in each of the semiconductor layers is higher. Also, on the basis of the underlying knowledge of the present inventor, a region is formed, around 100 μm from each groove, in which strain is retained. Here, to form semiconductor laser devices in a symmetric position with the respective cleavage surfaces serving as symmetric surfaces, under a condition that the remaining length is 50 μm or greater, the distance between two grooves that are located in a symmetric position relative to the cleavage surfaces before cleavage is 100 μm or greater. As such, strain is retained between the two grooves symmetrically located with respect to the cleavage surface at least before cleavage, thereby providing a favorable cleavage surface. This increases the reliability of the semiconductor laser device.

In the present embodiment, remaining length Lr1 may be less than 50 μm. With this, it is possible to reduce the strain in each of the semiconductor layers before and after cleavage, thereby further reducing warpage of semiconductor laser device 100 before cleavage. This thus further facilitates the handling of semiconductor laser device 100 before cleavage.

Alternatively, in the present embodiment, remaining length Lr1 may be 100 μm or greater. The remaining length of 100 μm or greater enables strain to be retained in the vicinity of the cleavage surface not only before but also after cleavage. This provides a favorable cleavage surface, thus increasing the reliability of semiconductor laser device 100.

In the present embodiment, remaining length Lr1 may be 50 μm or greater and less than 100 μm. The remaining length of 50 μm or greater enables strain to be retained in the vicinity of the cleavage surface before cleavage, and the remaining length of less than 100 μm reduces strain in the vicinity of the cleavage surface after cleavage. Semiconductor laser device 100 according to the present embodiment is thus capable of both having a favorable cleavage surface and reducing chip warpage.

In the present embodiment, each of substrate 110, n-type semiconductor layer 121, and light emitting layer 122 may comprise a nitride semiconductor. The use of a nitride semiconductor in each of the semiconductor layers can cause variations in an effective bandgap in light emitting layer 122 as a result of forming grooves 180. Having remaining length Lr1 that is longer than non-injection region length Ln1, however, semiconductor laser device 100 according to the present embodiment is capable of reducing a decrease in an effective bandgap in non-injection region 122b.

In the present embodiment, at least one p electrode 130 may include a plurality of p electrodes 130 that are arranged in a direction that is perpendicular to the resonance direction. Semiconductor laser device 100 including a plurality of p electrodes 130 serves as an array semiconductor laser device 100. With this, it is possible to provide a high-power semiconductor laser device 100.

Note that only the configuration at the side of output end face 101 such as groove 180 has been described above, but groove 180 may have the same structure also at the side of reflection end face 102. Stated differently, the remaining length, which is the distance between reflection end face 102 and that portion of groove 180 which is closest to p electrode 130, may be longer than the non-injection region length, which is the distance between reflection end face 102 and p electrode 130. Also, the other configuration such as groove 180 at the side of reflection end face 102 may be the same as that in output end face 101.

### Embodiment 2

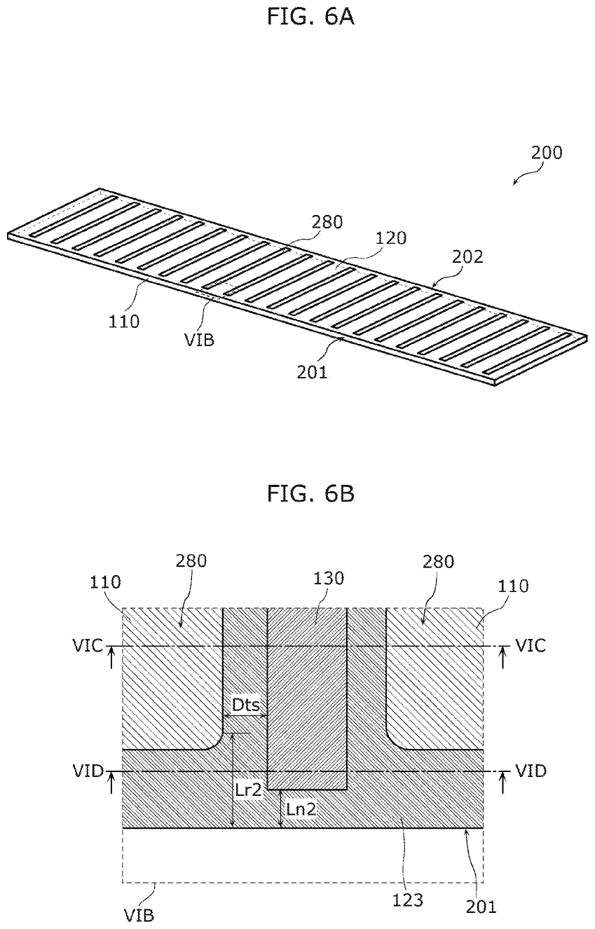

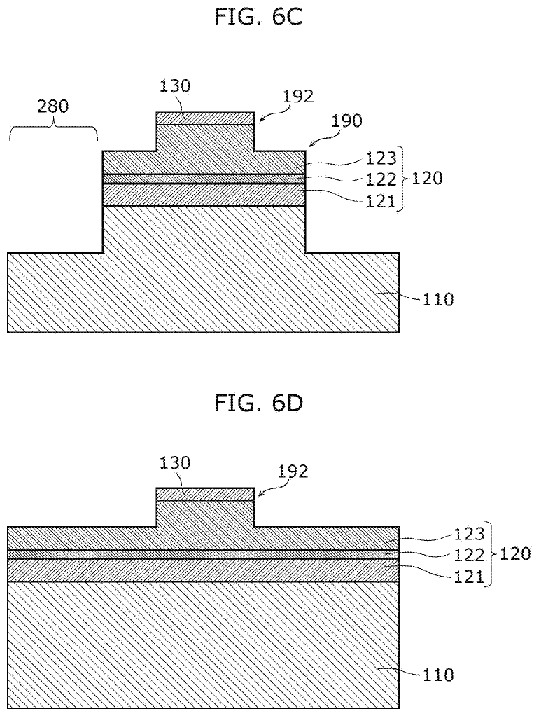

The following describes the semiconductor laser device according to Embodiment 2. The semiconductor laser device according to the present embodiment is different from semiconductor laser device 100 according to Embodiment 1 in the shape of grooves. With reference to FIG. 6A through FIG. 6D, the following describes the semiconductor laser device according to the present embodiment to mainly explain the difference from semiconductor laser device 100 according to Embodiment 1.

FIG. 6A is a schematic perspective view of an overall configuration of semiconductor laser device 200 according to the present embodiment. FIG. 6B is a partially enlarged plan view of semiconductor laser device 200 according to the present embodiment. FIG. 6B shows an enlarged view of the inside of broken line frame VIB in FIG. 6A. FIG. 6C and FIG. 6D are first and second cross-sectional views, respectively, of semiconductor laser device 200 according to the present embodiment. FIG. 6C and FIG. 6D show cross-sections cut along VIC-VIC line and VID-VID line in FIG. 6B, respectively.

Semiconductor laser device 200 according to the present embodiment, which is a device that outputs laser light, includes, as shown in FIG. 6A, output end face 201 that is an end face from which laser light is outputted and reflection end face 202 that is an end face at the rear side. Semiconductor laser device 200 includes substrate 110 and crystal growth layer 120 disposed on substrate 110. As shown in FIG. 6C and FIG. 6D, semiconductor laser device 200 further includes at least one p electrode 130. Also, as shown in FIG. 6A through FIG. 6C, at least one groove 280 is formed in semiconductor laser device 200.

As with grooves 180 in semiconductor laser device 100 according to Embodiment 1, at least one groove 280 in semiconductor laser device 200 according to the present embodiment extends from the upper surface of p-type semiconductor layer 123 to reach the lower surface of light emitting layer 122 as shown in FIG. 6C, and extends in the resonance direction of laser light as shown in FIG. 6A and FIG. 6B. As shown in FIG. 6B, remaining length Lr2, which is the distance between output end face 201 and that portion of groove 280 which is closest to p electrode 130, is longer than non-injection region length Ln2, which is the distance between output end face 201 and p electrode 130.

In the present embodiment, as shown in FIG. 6B, the width of groove 280 gradually decreases from that portion of groove 280 which is closest to p electrode 130 toward output end face 201. Stated differently, starting from the portion at which the distance to p electrode 130 takes minimum value Dts toward output end face 201, that side edge of groove 280 which is close to p electrode 130 is gradually distant from p electrode 130. In other words, that side edge of groove 280 which is close to p electrode 130 is inclined relative to the resonance direction of laser light, between output end face 201 and the portion at which the distance to p electrode 130 takes minimum value Dts.

Depending on the distance between groove 280 and p electrode 130, stress to be applied to light emitting layer 122 changes and so does the reflective index of light emitting layer 122. As in such case, a rapid change in the reflective index of light emitting layer 122 in a light propagation direction (i.e., the resonance direction of laser light) disturbs the light propagation. Semiconductor laser device 200 according to the present embodiment whose groove 280 gradually decreases in width is thus capable of attenuating changes in the reflective index of light emitting layer 122, thereby preventing the disturbance of light propagation.

In an example shown in FIG. 6B, that side edge of groove 280 which is close to p electrode 130 has a curvy shape in a plan view of substrate 110, but the shape of the side edge is not limited to this. For example, the side edge may have a step-like shape in a plan view of substrate 110, or may have a linear shape that is inclined relative to the resonance direction. Stated differently, the width of groove 280 may decrease stepwise or linearly.

### Embodiment 3

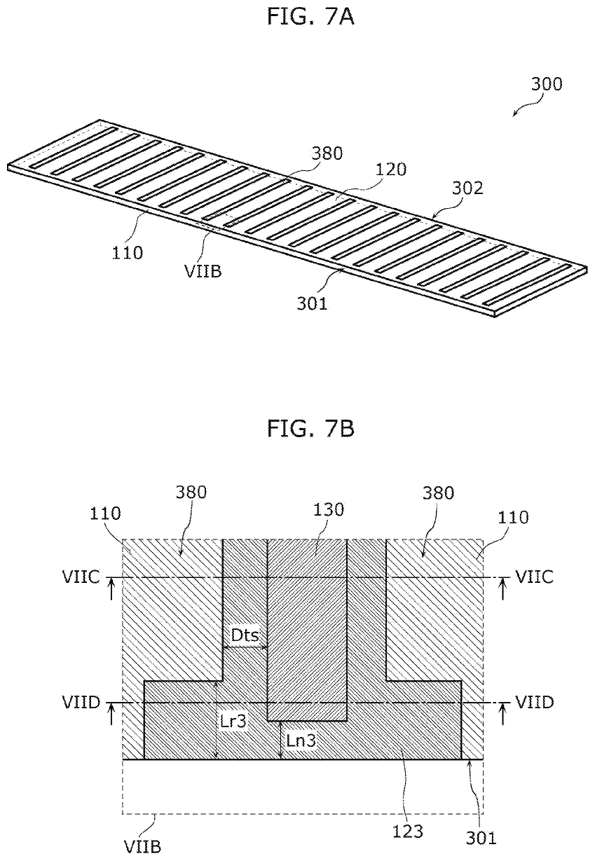

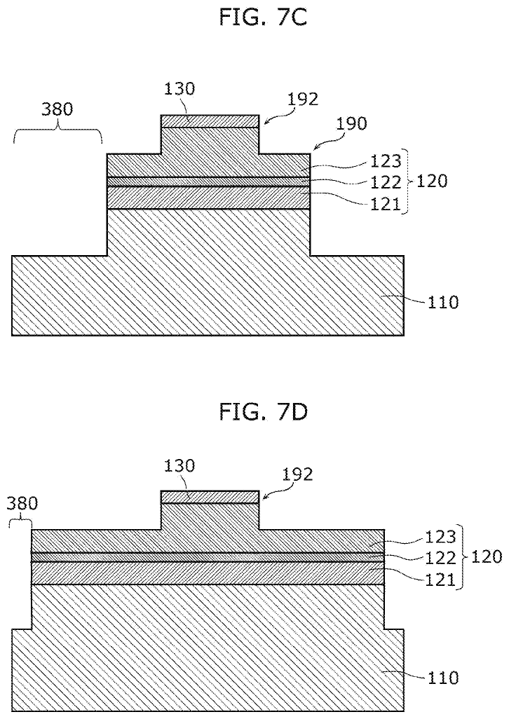

The following describes the semiconductor laser device according to Embodiment 3. The semiconductor laser device according to the present embodiment is different from semiconductor laser device 100 according to Embodiment 1 in that a groove extends to the output end face. With reference to FIG. 7A through FIG. 7D, the following describes the semiconductor laser device according to the present embodiment to mainly explain the difference from semiconductor laser device 100 according to Embodiment 1.

FIG. 7A is a schematic perspective view of an overall configuration of semiconductor laser device 300 according to the present embodiment. FIG. 7B is a partially enlarged plan view of semiconductor laser device 300 according to the present embodiment. FIG. 7B shows an enlarged view of the inside of broken line frame VIIB in FIG. 7A. FIG. 7C and FIG. 7D are first and second cross-sectional views, respectively, of semiconductor laser device 300 according to the present embodiment. FIG. 7C and FIG. 7D show cross-sections cut along VIIC-VIIC line and VIID-VIID line in FIG. 7B, respectively.

Semiconductor laser device 300 according to the present embodiment, which is a device that outputs laser light, includes, as shown in FIG. 7A, output end face 301 that is an end face from which laser light is outputted and reflection end face 302 that is an end face at the rear side. Semiconductor laser device 300 includes substrate 110 and crystal growth layer 120 disposed on substrate 110. As shown in FIG. 7C and FIG. 7D, semiconductor laser device 300 further includes at least one p electrode 130. Also, as shown in FIG. 7A through FIG. 7C, at least one groove 380 is formed in semiconductor laser device 300.

As with groove 180 in semiconductor laser device 100 according to Embodiment 1, at least one groove 380 in semiconductor laser device 300 according to the present embodiment extends from the upper surface of p-type semiconductor layer 123 to reach the lower surface of light emitting layer 122 as shown in FIG. 7C, and extends in the resonance direction of laser light as shown in FIG. 7A and FIG. 7B. As shown in FIG. 7B, remaining length Lr3, which is the distance between output end face 301 and that portion of groove 380 which is closest to p electrode 130, is longer than non-injection region length Ln3, which is the distance between output end face 301 and p electrode 130.

In the present embodiment, as shown in FIG. 7B, groove 380 extends to output end face 301. Stated differently, groove 380 is formed also in the portion of remaining length Lr3 of groove 380. Note, however, that in the portion of remaining length Lr3 of groove 380, the distance between groove 380 and p electrode 130 is greater than minimum value Dts of the distance between groove 380 and p electrode 130. This prevents a decrease in an effective bandgap in non-injection region 122b in light emitting layer 122 attributable to the portion of remaining length Lr3 of groove 380. Semiconductor laser device 300 according to the present embodiment is thus also capable of preventing the occurrence of COD.

### Embodiment 4

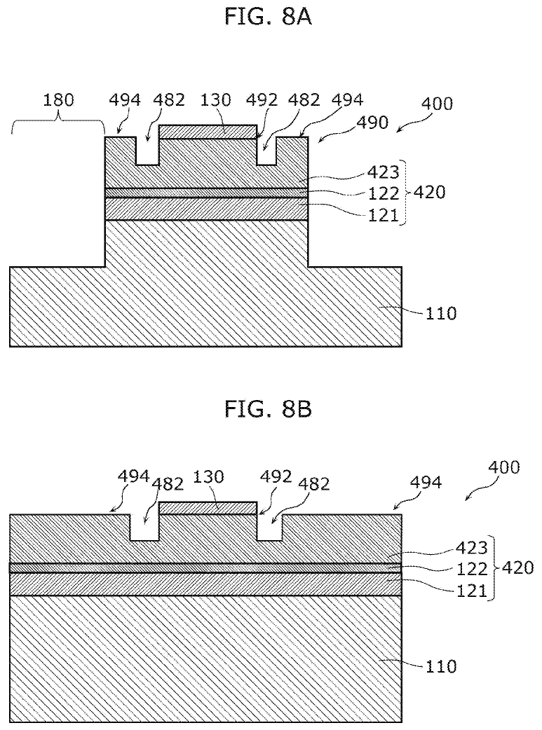

The following describes the semiconductor laser device according to Embodiment 4. The semiconductor laser device according to the present embodiment is different from semiconductor laser device 100 according to Embodiment 1 in the structure of the p-type semiconductor layer. With reference to FIG. 8A and FIG. 8B, the following describes the semiconductor laser device according to the present embodiment to mainly explain the difference from semiconductor laser device 100 according to Embodiment 1.

FIG. 8A and FIG. 8B are first and second cross-sectional views, respectively, of semiconductor laser device 400 according to the present embodiment. FIG. 8A and FIG. 8B are cross-sections of semiconductor laser device 400 according to the present embodiment, showing the cross-sections of the same positions as those of semiconductor laser device 100 according to Embodiment 1 shown in FIG. 5C and FIG. 5D, respectively.

Semiconductor laser device 400 according to the present embodiment includes substrate 110 and crystal growth layer 420 disposed on substrate 110. As shown in FIG. 8A and FIG. 8B, semiconductor laser device 400 further includes at least one p electrode 130. Also, as shown in FIG. 8A, at least one groove 180 is formed in semiconductor laser device 400 as with semiconductor laser device 100 according to Embodiment 1. With this, light emitting portion 490 is formed between two grooves 180.

In the present embodiment, crystal growth layer 420 includes n-type semiconductor layer 121, light emitting layer 122, and p-type semiconductor layer 423. n-type semiconductor layer 121 and light emitting layer 122 according to the present embodiment have the same structures as those of n-type semiconductor layer 121 and light emitting layer 122 according to Embodiment 1, respectively.

p-type semiconductor layer 423 according to the present embodiment, which is a p-type semiconductor layer disposed above light emitting layer 122, includes ridge portion 492 and lateral portions 494 located along the both lateral sides of ridge portion 492. Ridge portion 492 and lateral portions 494 are formed by forming, in p-type semiconductor laser 423, a pair of recessed portions 482 that extend in the resonance direction of laser light. Recessed portions 482 are formed by, for example, wet etching, dry etching, etc.

Semiconductor laser device 400 according to the present embodiment also achieves the same effects as those provided by semiconductor laser device 100 according to Embodiment 1.

In general, sidewall leakage can occur in a semiconductor laser device, where electric current flows from the p electrode to reach the substrate via the sidewalls of the crystal growth layer. However, semiconductor laser device 400 according to the present embodiment that includes lateral portions 494 is capable of increasing electrical resistance in the path from p electrode 130 to the sidewalls of crystal growth layer 420, thus reducing sidewall leakage.

Semiconductor laser device 400 according to the present embodiment is also capable of dispersing the stress applied to ridge portion 492 when p electrode 130 of semiconductor laser device 400 is mounted onto the mounting board, etc. This prevents ridge portion 492 from being damaged.

### Embodiment 5

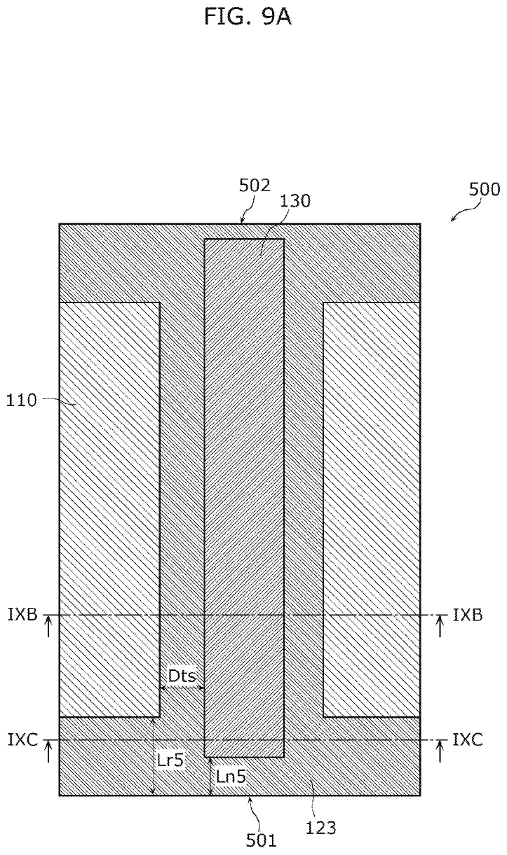

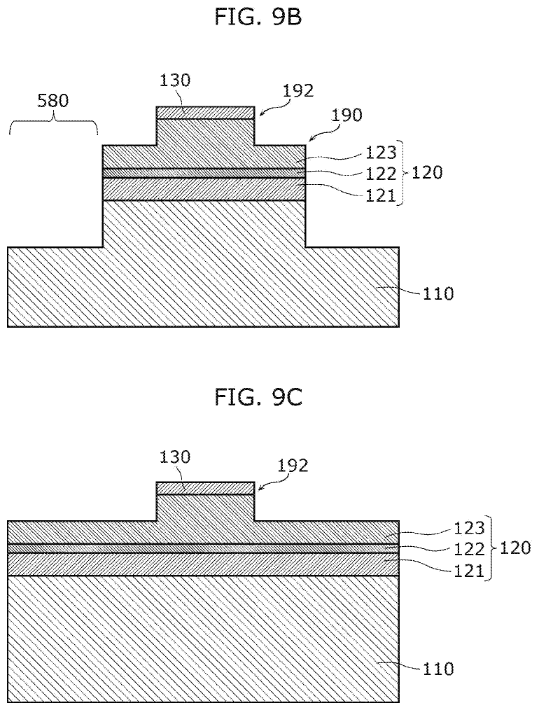

The following describes the semiconductor laser device according to Embodiment 5. The semiconductor laser device according to the present embodiment is different from semiconductor laser device 100 according to Embodiment 1 in that a single p electrode is included. With reference to FIG. 9A through FIG. 9C, the following describes the semiconductor laser device according to the present embodiment to mainly explain the difference from semiconductor laser device 100 according to Embodiment 1.

FIG. 9A is a schematic plan view of an overall configuration of semiconductor laser device 500 according to the present embodiment. FIG. 9B and FIG. 9C are first and second cross-sectional views, respectively, of semiconductor laser device 500 according to the present embodiment. FIG. 9B and FIG. 9C show cross-sections cut along IXB-IXB line and IXC-IXC line in FIG. 9A, respectively.

Semiconductor laser device 500 according to the present embodiment, which is a device that outputs laser light, includes, as shown in FIG. 9A, output end face 501 that is an end face from which laser light is outputted and reflection end face 502 that is an end face at the rear side. As shown in FIG. 9B and FIG. 9C, semiconductor laser device 500 includes substrate 110 and crystal growth layer 120 disposed on substrate 110. Semiconductor laser device 500 further includes a single p electrode 130. Also, as shown in FIG. 9B, two grooves 580 are formed in semiconductor laser device 500. With this, light emitting portion 190 is formed between two grooves 580.

As with groove 180 in semiconductor laser device 100 according to Embodiment 1, groove 580 in semiconductor laser device 500 according to the present embodiment extends from the upper surface of p-type semiconductor layer 123 to reach the lower surface of light emitting layer 122 as shown in FIG. 9B, and extends in the resonance direction of laser light as shown in FIG. 9A. Also, as shown in FIG. 9A, remaining length Lr5, which is the distance between output end face 501 and that portion of groove 580 which is closest to p electrode 130, is longer than non-injection region length Ln5, which is the distance between output end face 501 and p electrode 130.

Semiconductor laser device 500 according to the present embodiment also achieves the same effects as those provided by semiconductor laser device 100 according to Embodiment 1.

### [Variation, etc.]

The semiconductor laser device, etc. according to the present disclosure have been described above on the basis of the embodiments, but the present disclosure is not limited to the foregoing embodiments.

In the semiconductor laser devices in the foregoing embodiments, for example, each groove extends to substrate 110, but may not extend to substrate 110. Each groove is simply required to extend at least to the lower surface of light emitting layer 122.

In the foregoing embodiments, one or more grooves are formed consecutively in the resonance direction, but one or more grooves may be formed intermittently in the resonance direction. For example, each of the one or more grooves may by separated into a plurality of portions in the resonance direction.

The scope of the present disclosure also includes: an embodiment achieved by making various modifications to the foregoing embodiments that can be conceived by those skilled in the art; and another embodiment achieved by freely combining elements and functions in the foregoing embodiments without departing from the essence of the present disclosure.

For example, the structure of p-type semiconductor laser 423 of semiconductor laser device 400 according to Embodiment 4 may be applied to the p-type semiconductor layer of each of the semiconductor laser devices according to Embodiments 2, 3, and 5. Also, the structure of groove 280 of semiconductor laser device 200 according to Embodiment 2 may be applied to each of the semiconductor laser devices according to Embodiments 3 through 5.

### INDUSTRIAL APPLICABILITY

The semiconductor laser device according to the present disclosure is applicable for use, for example, in a processing device, etc. as a high-power and highly efficient light source.

1. A semiconductor laser device that outputs laser light, the semiconductor laser device comprising:
a substrate;
an n-type semiconductor layer disposed above the substrate;
a light emitting layer disposed above the n-type semiconductor layer;
a p-type semiconductor layer disposed above the light emitting layer; and
at least one p electrode disposed above the p-type semiconductor layer,
wherein at least one groove is formed that extends from an upper surface of the p-type semiconductor layer to reach a lower surface of the light emitting layer, and extends in a resonance direction of the laser light, and
a remaining length is longer than a non-injection region length, the remaining length being a distance between an output end face from which the laser light is outputted and a portion of the at least one groove, the non-injection region length being a distance between the output end face and the at least one p electrode, the portion being a portion that is closest to the at least one p electrode.

2. The semiconductor laser device according to claim 1,
wherein in the light emitting layer, an effective bandgap is greater in a non-injection region located between an injection region located directly below the at least one p electrode and the output end face than in the injection region.

3. The semiconductor laser device according to claim 1,
wherein a width of the at least one groove gradually decreases from the portion of the at least one groove that is closest to the at least one p electrode toward the output end face.

4. The semiconductor laser device according to claim 1,
wherein the remaining length is 50 μm or greater.

5. The semiconductor laser device according to claim 4,
wherein the remaining length is 100 μm or greater.

6. The semiconductor laser device according to claim 4,
wherein the remaining length is less than 100 μm.

7. The semiconductor laser device according to claim 1,
wherein each of the substrate, the n-type semiconductor layer, and the light emitting layer includes a nitride semiconductor.

8. The semiconductor laser device according to claim 1,
wherein the at least one p electrode includes a plurality of p electrodes that are arranged in a direction perpendicular to the resonance direction.

9. The semiconductor laser device according to claim 8,
wherein the at least one groove extends to the output end face.
